(19) United States
(12) Patent Application Publication
(10) Pub. No.: US 2005/0262423 A1
(43) Pub. Date: Nov. 24, 2005

(54) Majority detection in error recovery

(75) Inventors: Jingfeng Liu, Shrewsbury, MA (US); Bernie Rub, Sudbury, MA (US); Pei-hui Zheng, Medfield, MA (US)

Correspondence Address: David M. Sigmond;Maxtor Corporation, 2452 Clover Basin Drive, Longmont, CO, 80503, US

(73) Assignee: Maxtor Corporation

(21) Appl. No.: 11/135,978

(22) Filed: May 24, 2005

Related U.S. Application Data
(60) Provisional application No. 60/573,855, filed on May 24, 2004.

(51) Int. Cl. H03M 13/00; G06F 11/00

(52) U.S. Cl. 714/798

(57) ABSTRACT

A majority detector for error recovery provides hard and soft majority detection.

### CROSS-REFERENCE TO RELATED APPLICATIONS

This application claims priority from U.S. Provisional Patent Application No. 60/573,855, filed May 24, 2004, entitled “Majority Detection in Error Recovery” which is incorporated herein by reference.

### FIELD OF THE INVENTION

The present invention relates to error recovery.

### BRIEF DESCRIPTION OF THE DRAWINGS

FIG. 1 is a concept diagram of majority detection.

FIG. 2 is an embodiment of hard majority detection.

FIG. 3 is an embodiment of soft majority detection.

### DETAILED DESCRIPTION OF THE PREFERRED EMBODIMENTS

Although the present invention is described for use in a disk drive, it should be expressly understood that the present invention is applicable to other electronic systems, including data storage devices and communication channels. Furthermore, the description is not intended to limit the invention to the form disclosed herein. Consequently, variations and modifications commensurate with the following teachings, and skill and knowledge of the relevant art, are within the scope of the present invention.

Introduction

In hard drive, the signal SNR is shrinking because of the increasing storage density, and so is the margin. Advanced signal processing and coding methods are employed or being considered to be employed in hard drives. Good examples are parity check codes, media noise optimized Viterbi detector, and iterative soft decoding. All these signal processing methods are designed to operate on-the-fly, i.e., on the first pass of the disc revolution. Occasionally, when reading the marginal blocks, the read on the first pass may fail when the number of errors exceeds the capability of the Error Correction Code (ECC), which is normally Reed-Solomon (RS) code. The drive will then enter error recovery mode which tries to recover this ‘bad’ block by pre-defined retries. This is the moment that we need the detector to be as powerful as possible.

In this disclosure, we will propose a new detection method, majority detection, which can be fit naturally into the error recovery mode. Moreover, the implementation of majority detection involves only the firmware modifications without any additional hardware support. There are two versions of majority detection, hard majority detection, and soft majority detection. The evaluation of hard majority detection show that it can give around 0.3 order of magnitude gain over the media noise optimized Viterbi detector, i.e., the 7500M Media Noise Processor (MNP). The evaluation of soft majority detection is on-going, and believed to deliver another 0.3 order of magnitude gain based on prior experience on delta between soft and hard decoding of RS code.

Majority Detection

In error recovery mode, drives spend up to several hundreds of retries (the number of retries is limited by the specified time-out) trying to recover the bad block. Currently, the channel output NRZ bits of each retries are decoded independently by the ECC decoder.

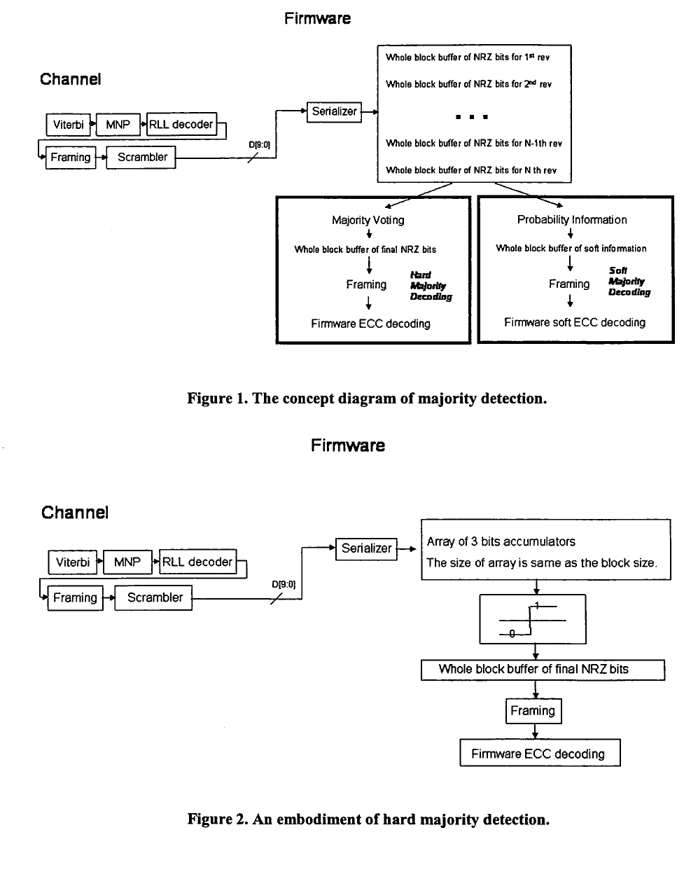

As shown in FIG. 1, the main idea of majority detection is to keep track of the channel output NRZ bits of several retries. A straightforward way to keep track is to use different buffers to buffer the NRZ bits for different retries. More efficient ways to implement this tracking are possible. There are two ways to use these tracked NRZ bits: making binary decision (called hard majority detection), or generating reliability information (called soft majority detection).

In hard majority detection, a majority voting is made among the NRZ bits for different retries to figure out the final NRZ bits to be used by firmware to do ECC decoding. Table 1 shows an example of how we do majority voting.

TABLE 1
Illustration of majority voting.

| | Bit Index | | | | | | | | |
|---|---|---|---|---|---|---|---|---|---|
| | 0 | 1 | 2 | 3 | 4 | 5 | 6 | 7 | 8 |
| First Retry | 1 | 0 | 0 | 0 | 1 | 1 | 0 | 1 | 0 |
| Second Retry | 1 | 0 | 0 | 1 | 1 | 1 | 1 | 0 | 0 |
| Third Retry | 1 | 1 | 0 | 0 | 1 | 0 | 0 | 0 | 1 |
| Majority Voting | 1 | 0 | 0 | 0 | 1 | 1 | 0 | 0 | 0 |

In soft majority detection, the reliability (soft) information is extracted from the NRZ bits for different retries, in addition to the final binary NRZ bits. The final binary bits and reliability information are used together by firmware to do soft ECC decoding. Examples of soft ECC decoding are GMD, chase and ASD soft decoding for RS code. Table 2 shows an example of generating reliability information from the NRZ bits for different retries.

TABLE 2
Illustration of a way to generate reliability information.

| | Bit Index | | | | | | | | |
|---|---|---|---|---|---|---|---|---|---|
| | 0 | 1 | 2 | 3 | 4 | 5 | 6 | 7 | 8 |
| First Retry | 1 | 0 | 0 | 0 | 1 | 1 | 0 | 1 | 0 |
| Second Retry | 1 | 0 | 0 | 1 | 1 | 1 | 1 | 0 | 0 |
| Third Retry | 1 | 1 | 0 | 0 | 1 | 0 | 0 | 0 | 1 |
| P(bit=1) | 1 | 0.33 | 0 | 0.33 | 1 | 0.67 | 0.33 | 0.33 | 0.33 |
| P(bit=0) | 0 | 0.67 | 1 | 0.67 | 0 | 0.33 | 0.67 | 0.67 | 0.67 |

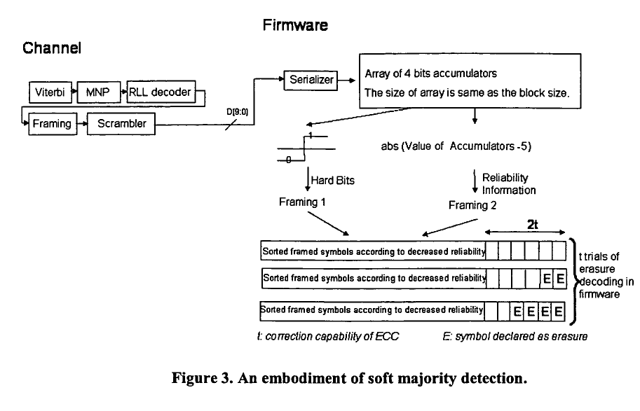

In the following, we will provide one embodiment of hard majority detection (shown in FIG. 2) and one embodiment of soft majority detection (shown in FIG. 3) for the case where we decide to keep track of NRZ bits for 9 different retries. Hard majority detection and soft majority detection can be use individually or in a hybrid fashion.

In one embodiment of hard majority detection (shown in FIG. 2), an array of 3 bits accumulators is used to count how many 1's in the 9 retries at each bit index. After 9 retries, if the value of the accumulator for the particular bit index is larger than 5, that bit is detected as 1, otherwise, detected as 0. The accumulators are reset to 0 afterwards. The binary detected bits are then framed into 10 bit symbols and to be ECC decoded.

In one embodiment of soft majority detection (shown in FIG. 3), the GSD soft decoding of RS code is used. An array of 4 bits accumulator is used to count the frequency of 1's for 9 retries at each bit index. After 9 retries, the binary decision for each bit index is made by a threshold detector with 5 as the threshold. The reliability information for each bit index is generated as follows:
rᵢ=abs(aᵢ−5)
where rᵢ is the reliability information for bit of index i, and aᵢ is the value of accumulator for bit of index i. The binary detected bits and their corresponding reliability information are then framed respectively to 10 bit symbols. It is straightforward to do framing for binary detected bits. By assuming that symbol k is consisted of bit i, i+1, . . . , i+8, and i+9, the reliability information Rₖ for symbol of index k is computed as follows:
Rₖ=min(rᵢ, rᵢ₊₁, . . . , rᵢ₊₈, rᵢ₊₉)

The next step is to sort the symbols according to decreased reliability Rₖ. By declaring the symbols of low reliability as erasures, we can do erasure decoding to utilize the erasure decoding capability power of RS code, which is 2t as opposed to t in normal decoding mode. As shown in FIG. 3, we have up to t trials of erasure decoding, where we gradually increase the number of declared erasures until 2t erasures.

### SUMMARY

In this disclosure, majority detection is proposed to be used in error recovery mode. Two versions of majority detection are proposed, hard majority detection and soft majority detection. For each version, one embodiment is proposed. The implementation of these embodiments involve only the firmware modifications without any additional hardware support. The performance of hard majority detection is found to give about 0.3 order of magnitude improvement. The evaluation of soft majority detection is currently under way, and believed to give another 0.3 order of magnitude improvement based on prior experience on delta between soft and hard decoding of RS code.

1. A majority detector for error recovery, comprising:
means for hard majority detection; and
means for soft majority detection.
